(19) United States
(12) Patent Application Publication
(10) Pub. No.: US 2025/0164779 A1
(43) Pub. Date: May 22, 2025

(54) DRIVE ELEMENT AND LIGHT DEFLECTION ELEMENT

(71) Applicant: Panasonic Intellectual Property Management Co., Ltd., Osaka (JP)

(72) Inventors: Kensuke MIHARA, Osaka (JP); Takami ISHIDA, Osaka (JP)

(21) Appl. No.: 19/029,536

(22) Filed: Jan. 17, 2025

Related U.S. Application Data
(63) Continuation of application No. PCT/JP2023/021680, filed on Jun. 12, 2023.

(30) Foreign Application Priority Data
Jul. 25, 2022 (JP) 2022-118315

(51) Int. Cl. G02B 26/08

(52) U.S. Cl. CPC G02B 26/0833

(57) ABSTRACT

A drive element includes: a movable part; a first support part extending along a rotation axis of the movable part and connected at one end thereof to the movable part; a pair of arm parts placed with the rotation axis located therebetween; a pair of coupling parts coupling the pair of arm parts to another end of the first support part; a second support part extending along the rotation axis and supporting the pair of coupling parts; a fixation part to which the second support part is connected; and drive parts configured to drive the arm parts, respectively. The second support part has higher rigidity than the first support part, and the pair of coupling parts are placed so as to be inclined toward the movable part side. An angle between each coupling part and the second support part is greater than 90° and equal to or less than 135°.

### CROSS REFERENCE TO RELATED APPLICATION

This application is a continuation of International Application No. PCT/JP2023/021680 filed on Jun. 12, 2023, entitled “DRIVE ELEMENT AND LIGHT DEFLECTION ELEMENT”, which claims priority under 35 U.S.C. Section 119 of Japanese Patent Application No. 2022-118315 filed on Jul. 25, 2022, entitled “DRIVE ELEMENT AND LIGHT DEFLECTION ELEMENT”. The disclosures of the above applications are incorporated herein by reference.

### BACKGROUND OF THE INVENTION

### Field of the Invention

The present invention relates to a drive element that rotates a movable part about a rotation axis, and a light deflection element using the drive element.

### Description of Related Art

In recent years, by using micro electro mechanical system (MEMS) technology, drive elements that rotate a movable part have been developed. In this type of drive element, a reflection surface is located on the movable part, thereby allowing scanning to be performed at a predetermined deflection angle with light incident on the reflection surface. This type of drive element is installed in image display devices such as head-up displays and head-mounted displays. In addition, this type of drive element can also be used in laser radars that use laser light to detect objects, etc.

Japanese Laid-Open Patent Publication No. 2019-082625 describes a drive element of a type in which a movable part is rotated by a so-called tuning fork vibrator. In this drive element, the movable part is connected to the tuning fork vibrator by a first connector extending along a rotation axis. In addition, the tuning fork vibrator is perpendicularly connected to a second connector extending along the rotation axis. The second connector is connected to a base. The base constitutes a fixation part for fixing the drive element to an installation surface. By driving the tuning fork vibrator, the movable part is rotated about the rotation axis, and a reflection surface located on the movable part is rotated accordingly.

In the drive element configured above, the driving efficiency of the movable part can be increased by making the rigidity of the second connector higher than the rigidity of the first connector. However, due to this difference in rigidity, when the movable part is driven, stress concentration may occur at the connection position between the second connector and the tuning fork vibrator, and the drive element may be damaged starting from the stress concentration point. In addition, due to such a difference in rigidity, the ease of rotation differs between the first connector and the second connector. Thus, in the configuration in which the tuning fork vibrator is perpendicularly connected to the second connector as in Japanese Laid-Open Patent Publication No. 2019-082625, a torque generated at the tuning fork vibrator is less likely to be smoothly transmitted to the first connector. This leads to a decrease in the driving efficiency of the movable part

### SUMMARY OF THE INVENTION

A first aspect of the present invention is directed to a drive element. The drive element according to this aspect includes: a movable part; a first support part extending along a rotation axis of the movable part and connected at one end thereof to the movable part; a pair of arm parts placed with the rotation axis located therebetween; a pair of coupling parts coupling the pair of arm parts to another end of the first support part; a second support part extending along the rotation axis and supporting the pair of coupling parts; a fixation part to which the second support part is connected; and drive parts configured to drive the arm parts, respectively. The second support part has higher rigidity than the first support part, and the pair of coupling parts are placed so as to be inclined toward the movable part side. An angle between each of the coupling parts and the second support part is greater than 90° and equal to or less than 135°.

In the drive element according to this aspect, since the pair of coupling parts are placed so as to be inclined toward the movable part side, and the angle between each of the coupling parts and the second support part is greater than 90° and equal to or less than 135°, even when the rigidity of the second support part is higher than that of the first support part, stress generated at the connection position between each coupling part and the second support part when the movable part is driven can be reduced, so that torques generated at the pair of arm parts can be efficiently transmitted to the first support part. Therefore, it is possible to effectively increase the driving efficiency of the movable part while reducing the stress generated when the movable part is driven.

A second aspect of the present invention is directed to a light deflection element. The light deflection element according to this aspect includes the drive element according to the first aspect and a reflection surface located on the movable part.

Since the light deflection element according to this aspect includes the drive element according to the first aspect, the driving efficiency of the movable part can be increased. Therefore, the reflection surface allows deflection of and scanning with light to be efficiently performed at a high deflection angle.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a perspective view showing a configuration of a drive element according to Embodiment 1;

FIG. 2 is a plan view showing the configuration of the drive element according to Embodiment 1;

FIG. 3 is a perspective view showing a configuration of a drive element according to a comparative example;

FIG. 4 is a plan view of the drive element for illustrating simulation conditions, according to Embodiment 1;

FIG. 5 is a diagram schematically showing a resonance mode used in simulation, according to Embodiment 1;

FIG. 6 is a graph showing a simulation result of maximum stress and a deflection angle according to Embodiment 1;

FIG. 7 is a plan view showing a configuration of the drive element in the case where an angle between each coupling part and each second support part is 150°, according to Embodiment 1;

FIG. 8 is a plan view showing a configuration of a drive element according to Embodiment 2;

FIG. 9 is a graph showing a simulation result of a deflection angle according to Embodiment 2;

FIG. 10 is a perspective view showing a configuration of a drive element according to Embodiment 3;

FIG. 11A is a plan view showing a configuration of a first drive unit of a drive element according to Modification 1;

FIG. 11B is a plan view showing a configuration of a first drive unit of a drive element according to Modification 2;

FIG. 12A is a plan view showing a configuration of a first drive unit of a drive element according to Modification 3; and

FIG. 12B is a plan view showing a configuration of a first drive unit of a drive element according to Modification 4.

It should be noted that the drawings are solely for description and do not limit the scope of the present invention by any degree.

### DETAILED DESCRIPTION

Hereinafter, embodiments of the present invention will be described with reference to the drawings.

In each embodiment described below, a reflection surface is located on a movable part of a drive element, whereby a light deflection element is configured. For convenience, in the drawings, X, Y, and Z axes that are orthogonal to each other are additionally shown. The Y-axis direction is a direction parallel to the rotation axis of the drive element, and the Z-axis direction is a direction perpendicular to the reflection surface located on the movable part.

### Embodiment 1

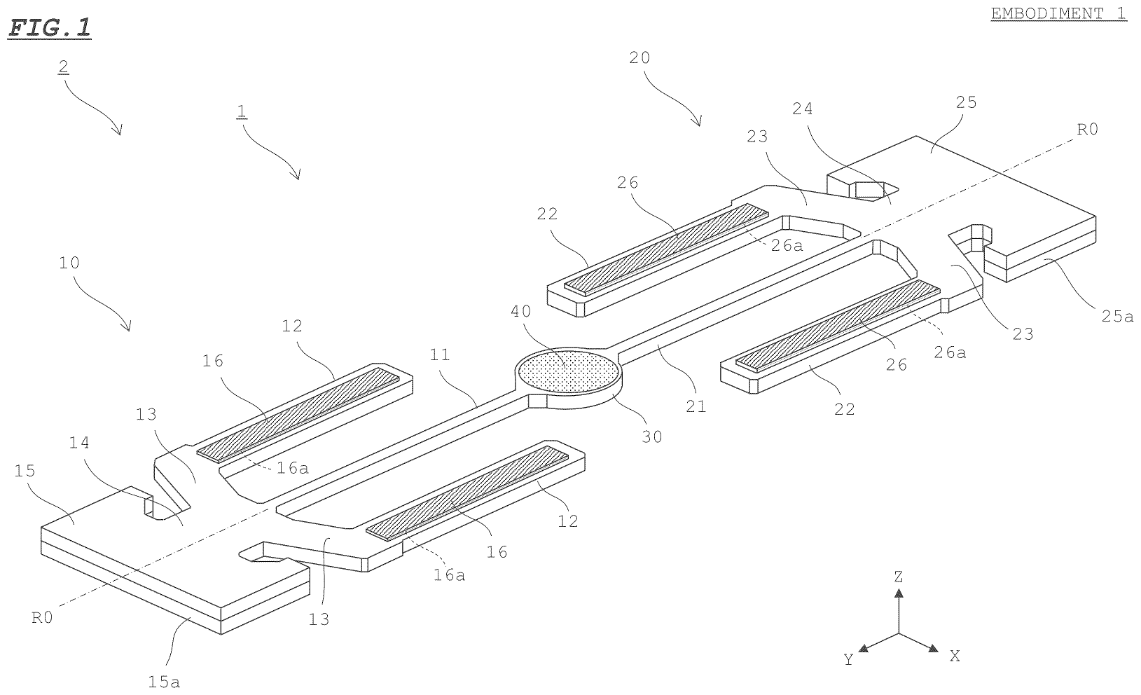

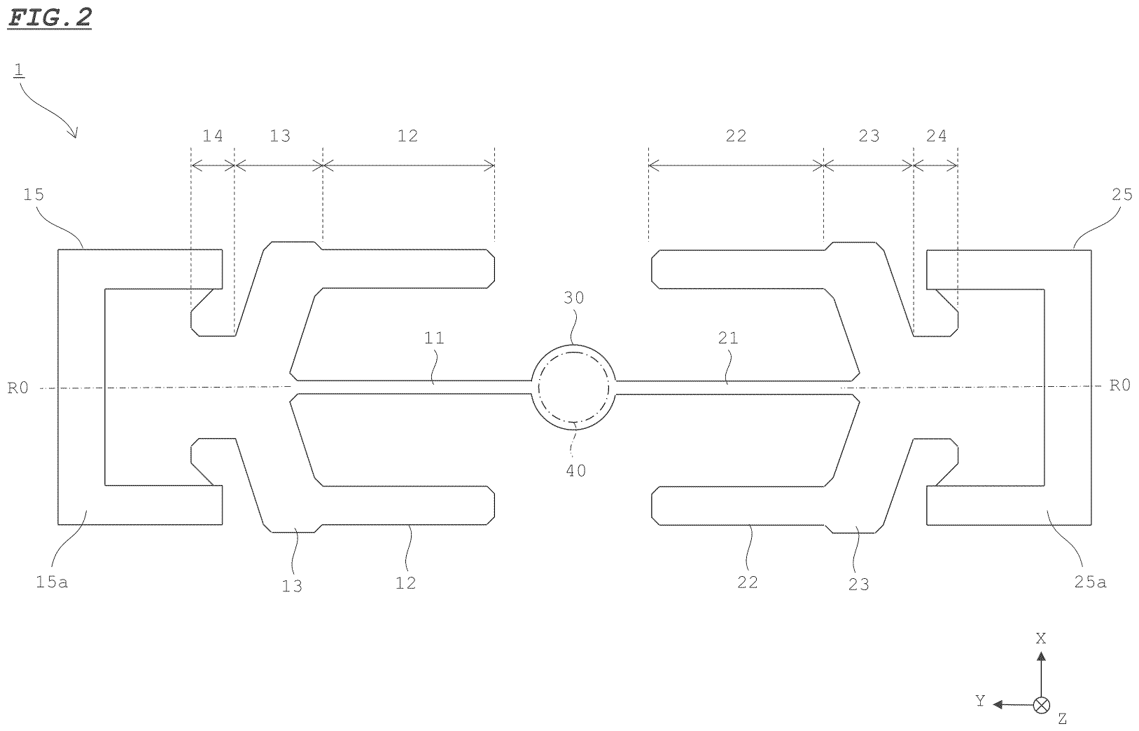

FIG. 1 is a perspective view showing a configuration of a drive element 1, and FIG. 2 is a plan view showing the configuration of the drive element 1. FIG. 2 shows a plan view of the drive element 1 as viewed from the lower surface side (Z-axis negative side).

As shown in FIG. 1 and FIG. 2, the drive element 1 includes a first drive unit 10, a second drive unit 20, and a movable part 30. In addition, a reflection surface 40 is located on the upper surface of the movable part 30, whereby a light deflection element 2 is configured. The drive element 1 has a symmetrical shape in the X-axis direction and the Y-axis direction in a plan view.

The first drive unit 10 and the second drive unit 20 rotate the movable part 30 about a rotation axis R0 in response to a drive signal supplied thereto from a drive circuit which is not shown. The reflection surface 40 reflects light incident thereon from above the movable part 30, in a direction corresponding to a deflection angle of the movable part 30. Accordingly, as the movable part 30 rotates, the light (e.g., laser light) incident on the reflection surface 40 is deflected and scanning is performed with this light. The movable part 30 and the reflection surface 40 may be formed of the same member.

The first drive unit 10 includes a first support part 11, a pair of arm parts 12, a pair of coupling parts 13, a second support part 14, a fixation part 15, and drive parts 16.

The first support part 11 extends along the rotation axis R0 of the movable part 30 and is connected at one end (end portion on the Y-axis negative side) thereof to the movable part 30. The first support part 11 has a rod-like shape. The width of the first support part 11 in the X-axis direction is constant except at both ends thereof. The widths at both ends of the first support part 11 gradually widen. A cross-section of the first support part 11 taken along the X-Z plane at the center of the first support part 11 has a substantially square shape. The cross-sectional shape of the first support part 11 may be another shape such as a circular shape.

The pair of arm parts 12 are placed symmetrically with the rotation axis R0 located therebetween. The pair of arm parts 12 extend parallel to the rotation axis R0. Each arm part 12 has a pseudo-rectangular shape having two rounded corners on the Y-axis negative side in a plan view.

The pair of coupling parts 13 couple the pair of arm parts 12 to the other end (end portion on the Y-axis positive side) of the first support part 11. The pair of coupling parts 13 extend so as to be separated from the rotation axis R0 in the X-axis positive and negative directions. More specifically, the directions in which the pair of coupling parts 13 extend are not perpendicular to the rotation axis R0, but are inclined in the direction (Y-axis negative direction) toward the movable part 30 with respect to a direction perpendicular to the rotation axis R0. That is, the pair of coupling parts 13 are placed so as to be inclined toward the movable part 30 side. The pair of coupling parts 13 are each placed so as to be further away from the rotation axis R0 at the distal end thereof than at the proximal end thereof. The width of each coupling part 13 in a horizontal direction perpendicular to the direction in which the coupling part 13 extends is constant except at both ends thereof.

The second support part 14 extends along the rotation axis R0 and supports the pair of coupling parts 13. The width of the second support part 14 in the X-axis direction is constant except at an end portion on the fixation part 15 side thereof. The width of the end portion of the first support part 11 on the fixation part 15 side gradually widens. The second support part 14 is connected to the fixation part 15.

The fixation part 15 is for fixing the drive element 1 to an installation surface. The thicknesses of end portions on the X-axis positive and negative sides and an end portion on the Y-axis positive side of the fixation part 15 are larger than that of the other portion of the fixation part 15. These portions having the larger thicknesses are installed on the installation surface.

The two drive parts 16 drive the pair of arm parts 12, respectively. The two drive parts 16 are piezoelectric drivers. The two drive parts 16 are formed on the upper surfaces of the pair of arm parts 12, respectively.

The second drive unit 20 includes a first support part 21, a pair of arm parts 22, a pair of coupling parts 23, a second support part 24, a fixation part 25, and drive parts 26. The configuration of the second drive unit 20 is the same as that of the first drive unit 10. The first drive unit 10 and the second drive unit 20 are placed in orientations opposite to each other with the movable part 30 located therebetween. The first support part 11 of the first drive unit 10 and the first support part 21 of the second drive unit 20 are connected to the movable part 30.

The pair of arm parts 12 and the coupling parts 13 constitute a tuning fork vibrator. In addition, the pair of arm parts 22 and the coupling parts 23 constitute a tuning fork vibrator. In the first drive unit 10, when the pair of arm parts 12 are driven by the two drive parts 16, the first support part 11 is rotated about the rotation axis R0. In addition, in the second drive unit 20, when the pair of arm parts 22 are driven by the two drive parts 26, the first support part 21 is rotated about the rotation axis R0. By performing control such that the rotation directions of the first support parts 11 and 21 are the same, the movable part 30 is rotated.

The drive parts 16 and 26 are composed of piezoelectric drivers. The drive parts 16 and 26 (piezoelectric drivers) each have a lamination structure in which electrode layers are placed on the upper and lower sides of a piezoelectric thin film 16a or 26a having a predetermined thickness, respectively.

Each piezoelectric thin film 16a or 26a is made of, for example, a piezoelectric material having a high piezoelectric constant, such as lead zirconate titanate (PZT). The electrode layers are made of a material having low electrical resistance and high heat resistance, such as platinum (Pt). Each piezoelectric driver is placed on the upper surface of the arm part 12 or 22 by forming the lamination structure, which includes the piezoelectric thin film 16a or 26a and the electrode layers on the upper and lower sides thereof, on the upper surface of the arm part 12 or 22 by a sputtering method or the like.

A substrate of the drive element 1 has the same contour as the drive element 1 in a plan view, and has a constant thickness. The reflection surface 40 and the drive parts 16 and 26 (piezoelectric drivers) are placed in corresponding regions of the upper surface of the substrate. In addition, layers 15a and 25a made of a predetermined material are further formed on the lower surfaces of regions, of the substrate, corresponding to the outer circumferences of the fixation parts 15 and 25, thereby increasing the thicknesses of the fixation parts 15 and 25. Therefore, the thickness of the drive element 1 is constant except in the regions where the layers 15a and 25a are formed. The material of the layers 15a and 25a may be a material different from that of the substrate, or may be the same material as that of the substrate.

The substrate is, for example, integrally formed from silicon or the like. However, the material forming the substrate is not limited to silicon, and may be another material. The material forming the substrate is preferably a material having high mechanical strength and Young's modulus, such as metal, crystal, glass, and resin. As such a material, in addition to silicon, titanium, stainless steel, Elinvar, a brass alloy, etc., can be used. The same applies to the material of the layers 15a and 25a of the fixation parts 15 and 25.

Meanwhile, in the drive element 1 shown in FIGS. 1 and 2, the rigidity of the second support parts 14 and 24 around the rotation axis R0 is made higher than that of the first support parts 11 and 21 by making the widths in the X-axis direction of the second support parts 14 and 24 wider than the widths in the X-axis direction of the first support parts 11 and 21. By making the rigidity of the second support parts 14 and 24 higher than that of the first support parts 11 and 21 as described above, the driving efficiency of the movable part 30 can be increased. On the other hand, however, if the rigidity of the second support parts 14 and 24 is made higher than that of the first support parts 11 and 21 as described above, stress is generated at the connection positions between the second support parts 14 and 24 and the coupling parts 13 and 23 when the movable part 30 is driven.

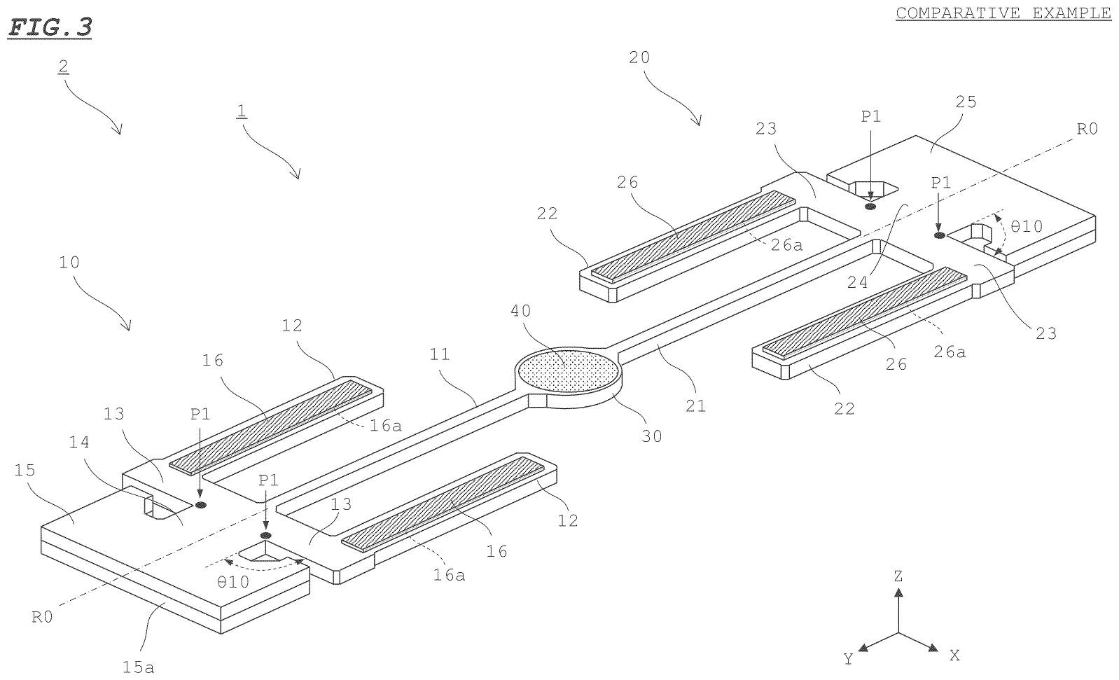

FIG. 3 is a perspective view showing a configuration of a drive element 1 according to a comparative example.

In the comparative example, the directions in which the pair of coupling parts 13 extend are different from those in the configuration of Embodiment 1 in FIG. 1. The other configuration of the comparative example is the same as the configuration of Embodiment 1.

In the comparative example, the pair of coupling parts 13 extend so as to be separated from the rotation axis R0 in the X-axis positive and negative directions, and the directions in which the coupling parts 13 extend are perpendicular to the rotation axis R0. Similarly, the pair of coupling parts 23 extend so as to be separated from the rotation axis R0 in the X-axis positive and negative directions, and the directions in which the coupling parts 23 extend are perpendicular to the rotation axis R0. That is, the pair of coupling parts 13 and the pair of coupling parts 23 are perpendicularly connected to the second support parts 14 and 24, respectively. Therefore, an angle θ10 between each coupling part 13 and the second support part 14 is 90°, and an angle θ10 between each coupling part 23 and the second support part 24 is also 90°.

In the case where the respective coupling parts 13 and 23 are perpendicularly connected to the second support parts 14 and 24 as described above, if the rigidity of the second support parts 14 and 24 is made higher than that of the first support parts 11 and 21 as described above, high stress is concentrated at the connection positions between the second support parts 14 and 24 and the coupling parts 13 and 23, that is, at positions P1 in FIG. 3. Thus, the drive element 1 may be damaged starting from these stress concentration points (positions P1).

In the configuration in which the rigidity of the second support parts 14 and 24 is higher than that of the first support parts 11 and 21 as described above, the ease of rotation differs between the first support parts 11 and 21 and the second support parts 14 and 24. Therefore, in the configuration in which the pair of coupling parts 13 and the pair of coupling parts 23 are perpendicularly connected to the second support parts 14 and 24, respectively, as in the comparative example, torques generated at the pair of arm parts 12 and the pair of arm parts 22 are less likely to be smoothly transmitted to the first support parts 11 and 21, resulting in a decrease in the driving efficiency of the movable part 30.

Thus, in Embodiment 1, in order to solve these problems, as shown in FIGS. 1 and 2, the pair of coupling parts 13 and the pair of coupling parts 23 are placed so as to be inclined toward the movable part 30 side, and the angle between each coupling part 13 or 23 and each second support part 14 or 24 is set to be greater than 90°. Accordingly, compared to the case where the respective coupling parts 13 and 23 are perpendicularly connected to the second support parts 14 and 24 as in the above comparative example, stress generated at the connection positions between the second support parts 14 and 24 and the coupling parts 13 and 23 can be reduced, and the driving efficiency of the movable part 30 can be increased.

Hereinafter, examination (simulation) performed by the inventors in order to confirm these effects will be described.

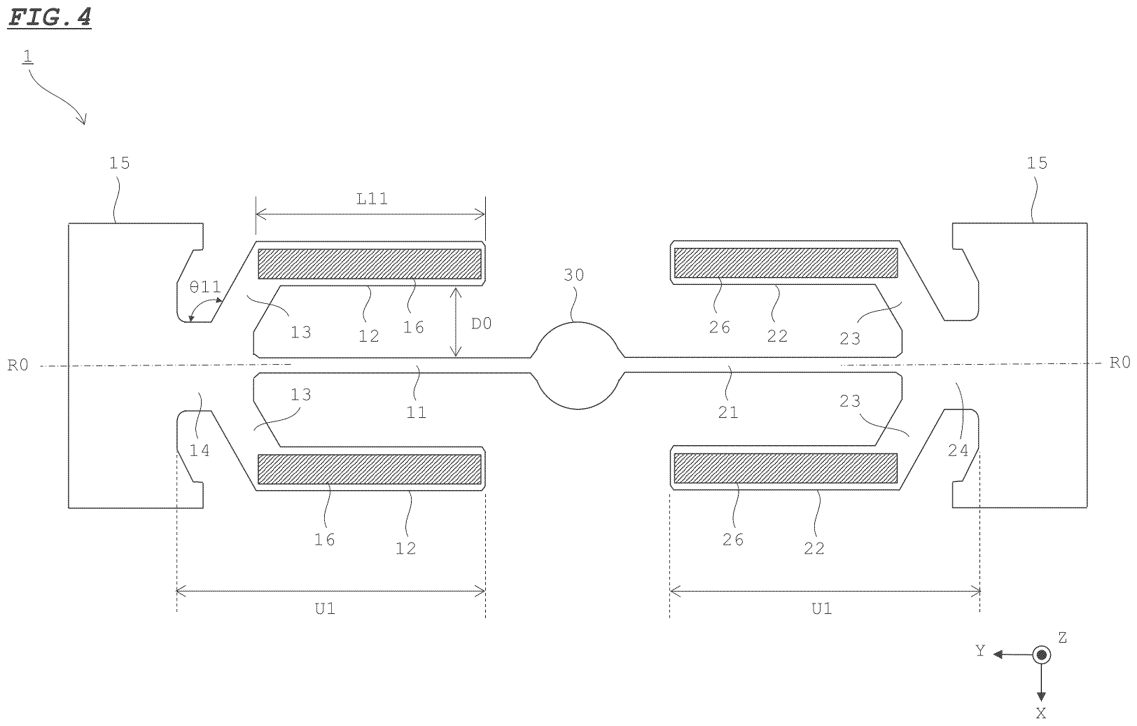

FIG. 4 illustrates simulation conditions.

FIG. 4 shows a plan view of a drive element 1 having the same configuration as in Embodiment 1 above. In the simulation, an interval D0 between each arm part 12 or 22 and each first support part 11 or 21 was fixed at a predetermined value. In addition, the resonance frequency of a tuning fork part U1 composed of the pair of arm parts 12, the pair of coupling parts 13, the second support part 14, and the two drive parts 16 and the resonance frequency of a tuning fork part U1 composed of the pair of arm parts 22, the pair of coupling parts 23, the second support part 24, and the two drive parts 26 were fixed at a predetermined value. This is because the driving efficiency of the movable part 30 can be increased by matching the resonance frequency of a portion composed of these tuning fork parts U1 with the resonance frequency of a portion composed of the first support parts 11 and 21 and the movable part 30.

Under these conditions, an angle θ between each coupling part 13 or 23 and each second support part 14 or 24 was changed in a range of 90° or more by changing the inclination of the pair of coupling parts 13 and the pair of coupling parts 23. For convenience, FIG. 4 shows the case where the angle θ is θ11) (120°). Since the resonance frequency of each tuning fork part U1 is fixed at the predetermined value as described above, as the angle θ changes, the length of each arm part 12 or 22 also changes. FIG. 4 shows a length L11 of each arm part 12 or 22 in the case where the angle θ is θ11) (120°).

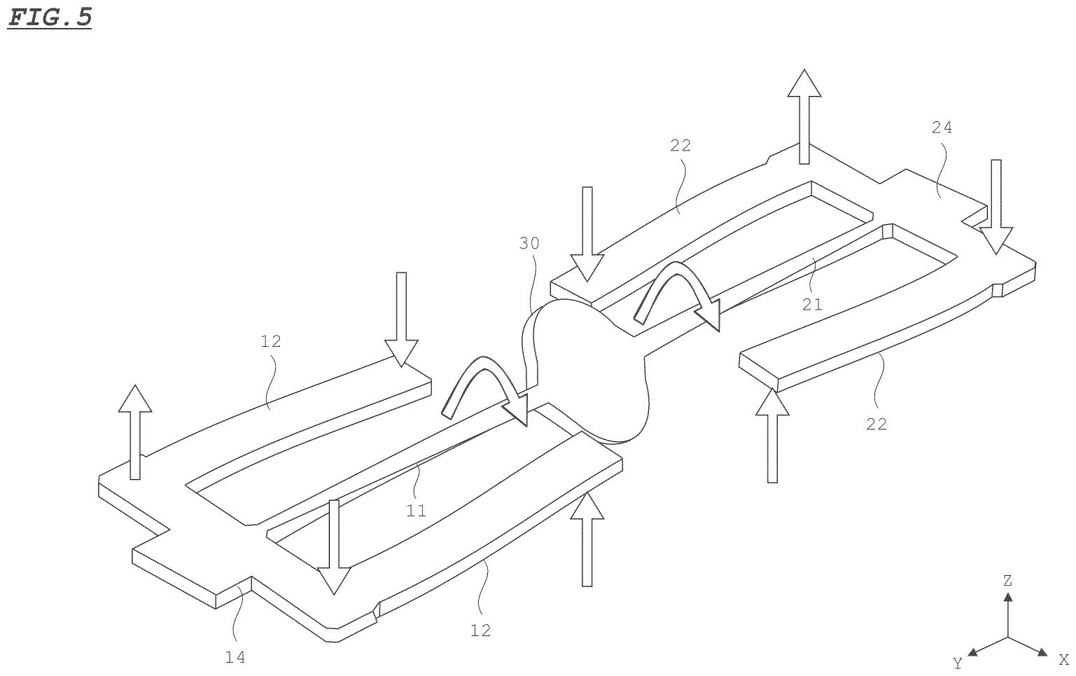

For each angle θ, the maximum stress and the deflection angle of the movable part 30 when each tuning fork part U1 was resonated were obtained by simulation. As shown in FIG. 5, each tuning fork part U1 was resonated in a mode in which the distal end and the proximal end of each arm part 12 or 22 move in opposite directions. In FIG. 5, arrows in the Z-axis direction indicate the movement directions of portions, and curved arrows indicate the rotation directions (torsion directions) of the first support parts 11 and 21.

The maximum stress was obtained as maximum stress generated at the connection positions between the pair of coupling parts 13 and the second support part 14 and the connection positions between the pair of coupling parts 23 and the second support part 24 when each tuning fork part U1 was resonated such that the deflection angle of the movable part 30 (total optical angle of the reflection surface 40) was 65°. In addition, the deflection angle was obtained as a deflection angle (total optical angle) when a voltage of 10 Vpp was applied to the drive parts 16 and 26 (piezoelectric drivers).

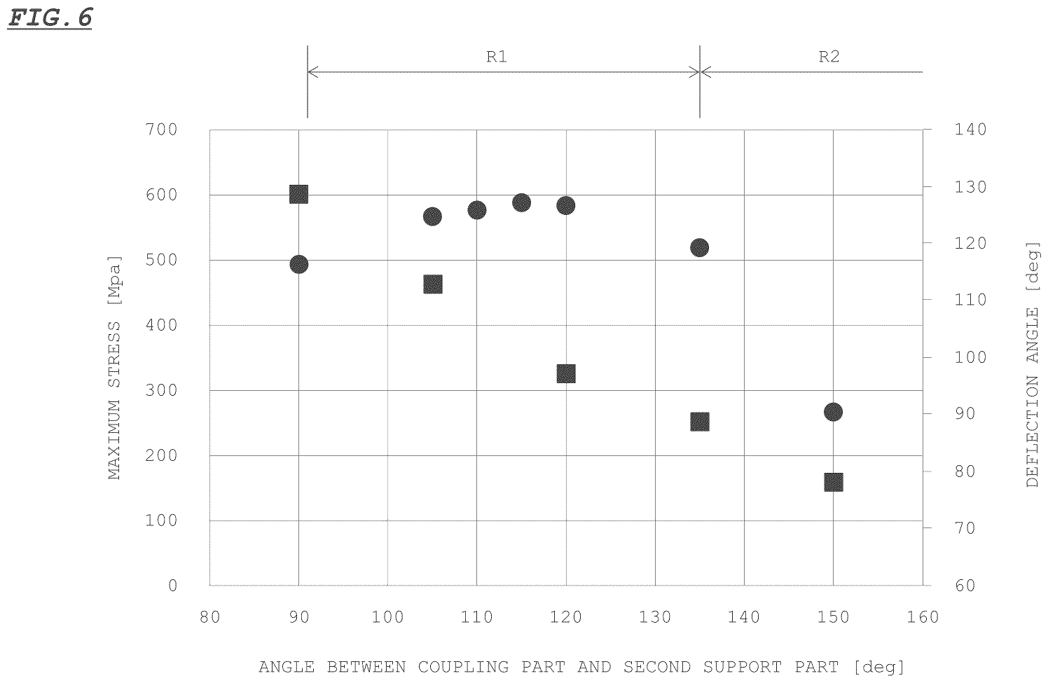

FIG. 6 is a graph showing a simulation result of the maximum stress and the deflection angle.

The horizontal axis of the graph in FIG. 6 indicates the angle between each coupling part 13 or 23 and each second support part 14 or 24, that is, the above-described angle θ. In addition, the vertical axis on the left side indicates the above-described maximum stress, and the vertical axis on the right side indicates the above-described deflection angle (total optical angle). Each square plot shows the maximum stress, and each circular plot shows the deflection angle.

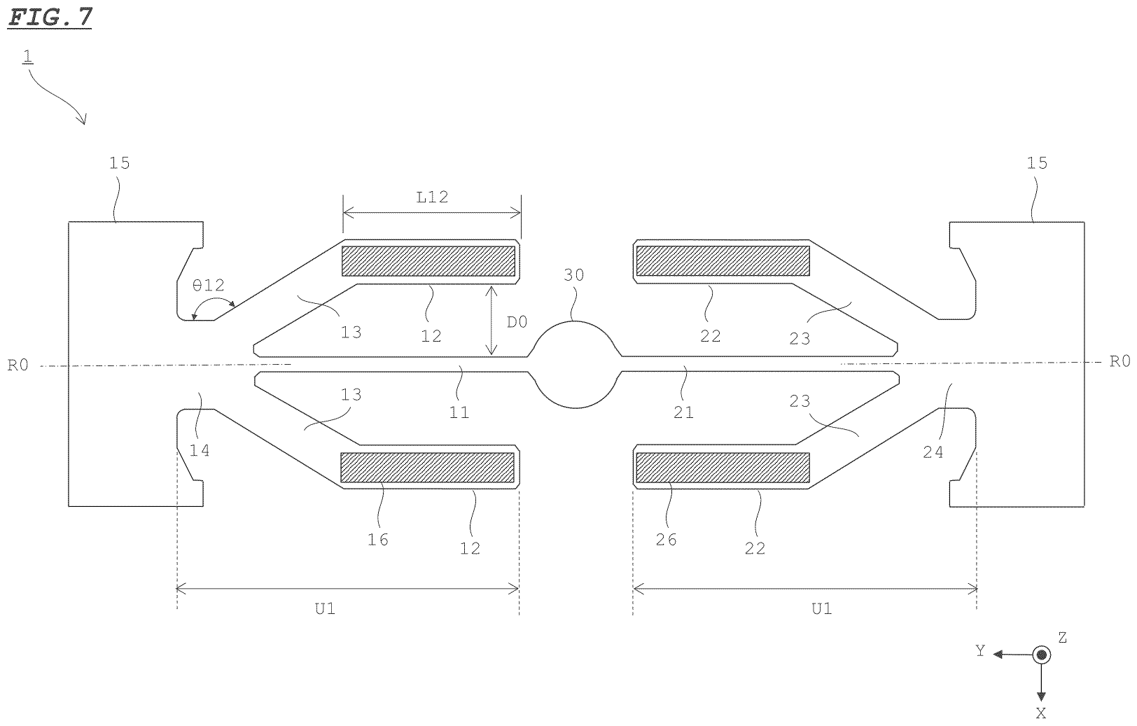

From the simulation result in FIG. 6, it is found that the maximum stress decreases as the angle θ increases from 90°. On the other hand, the deflection angle increased as the angle θ increased in the range where the angle θ was greater than 90° and equal to or less than around 115°, but when the angle θ exceeded around 115°, the deflection angle decreased as the angle θ increased. When the angle θ exceeded 135°, the deflection angle was lower than in the case of the comparative example in which the angle θ is 90°. This is because, as shown in FIG. 7, since the resonance frequency of each tuning fork part U1 is fixed at the predetermined value, the length of each arm part 12 or 22 shortens as the angle θ increases, so that a torque generated by the tuning fork part U1 is decreased. FIG. 7 shows a length L12 of each arm part 12 or 22 in the case where the angle θ is θ12) (150°). The length L12 is much shorter than the length L11 in FIG. 4.

Therefore, from the above simulation result, it can be said that, by setting the angle θ to be greater than 90° and equal to or less than about 135°, the maximum stress can be reduced and the driving efficiency can be improved compared to the comparative example shown in FIG. 3. Accordingly, it is possible to effectively increase the driving efficiency of the movable part 30 while reducing the stress generated when the movable part 30 is driven.

### Effects of Embodiment 1

According to Embodiment 1, the following effects can be achieved.

The pairs of coupling parts 13 and 23 are placed so as to be inclined toward the movable part 30 side, and the angle between each coupling part 13 or 23 and each second support part 14 or 24 is set to be greater than 90° and equal to or less than 135°. Accordingly, as shown in the simulation result in FIG. 6, even in the case where the rigidity of the second support parts 14 and 24 is higher than that of the first support parts 11 and 21, stress generated at the connection positions between the coupling parts 13 and 23 and the second support parts 14 and 24 when the movable part 30 is driven can be reduced, so that torques generated at the pairs of arm parts 12 and 22 can be efficiently transmitted to the first support parts 11 and 21. Therefore, it is possible to effectively increase the driving efficiency of the movable part 30 while reducing the stress generated when the movable part 30 is driven.

Here, as shown in the simulation result in FIG. 6, the angle between each coupling part 13 or 23 and each second support part 14 or 24 is preferably set around the range of 110° or more and 120° or less, and is further preferably set to around 115°. Accordingly, the driving efficiency of the movable part 30 can be increased the most.

As shown in FIG. 1 and FIG. 2, the pair of arm parts 12 and the pair of arm parts 22 extend parallel to the rotation axis R0. Accordingly, it is possible to reduce the stress and improve the driving efficiency of the movable part 30 as shown in the simulation result in FIG. 6, while keeping the outer shape of the drive element 1 in a plan view compact.

As shown in FIG. 1 and FIG. 2, the first drive unit 10, which includes the first support part 11, the pair of arm parts 12, the pair of coupling parts 13, the second support part 14, the fixation part 15, and the drive parts 16, and the second drive unit 20, which includes the first support part 21, the pair of arm parts 22, the pair of coupling parts 23, the second support part 24, the fixation part 25, and the drive parts 26, are placed in the orientations opposite to each other with the movable part 30 located therebetween, and the first support parts 11 and 21 of the respective drive units are connected to the movable part 30. Thus, by supporting and driving the movable part 30 by each drive unit, the movable part 30 can be stably driven with a larger torque.

As shown in FIG. 1, the drive parts 16 and 26 have the piezoelectric thin films 16a and 26a as drive sources. Accordingly, the arm parts 12 and 22 can be smoothly driven.

As shown in FIG. 1, the light deflection element 2 is configured by the drive element 1 and the reflection surface 40 placed on the movable part 30. Accordingly, the driving efficiency of the movable part 30 can be increased as described above, so that the reflection surface 40 allows deflection of and scanning with light to be efficiently performed at a high deflection angle.

### Embodiment 2

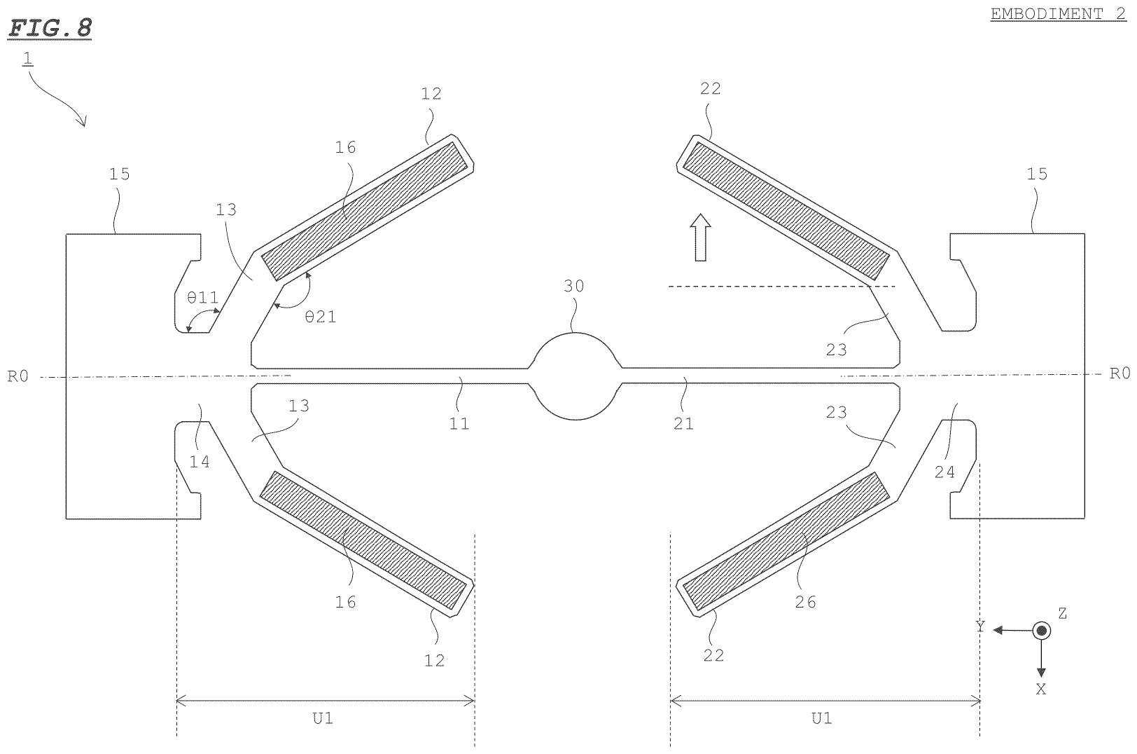

FIG. 8 is a plan view showing a configuration of a drive element 1 according to Embodiment 2.

In Embodiment 2, the placement of the pair of arm parts 12 and the pair of arm parts 22 is different from that in Embodiment 1. The other configuration of Embodiment 2 is the same as that of Embodiment 1. In Embodiment 2 as well, the drive element 1 has a symmetrical shape in the X-axis direction and the Y-axis direction in a plan view. In addition, in Embodiment 2 as well, the reflection surface 40 is formed on the upper surface of the movable part 30, whereby the light deflection element 2 is configured.

As shown in FIG. 8, the pair of arm parts 12 and the pair of arm parts 22 are each placed such that the distal ends thereof are open. That is, the pair of arm parts 12 are placed such that the distance therebetween increases toward the distal ends thereof. Similarly, the pair of arm parts 22 are placed such that the distance therebetween increases toward the distal ends thereof. Each pair of arm parts 12 or 22 are each placed obliquely with respect to the rotation axis R0 so as to be further away from the rotation axis R0 at the distal end thereof than at the proximal end thereof.

When the pairs of arm parts 12 and 22 are placed as described above, an angle (θ21 in FIG. 8) between the rotation axis R0 side of each arm part 12 or 22 and the coupling part 13 or 23 to which this arm part 12 or 22 is connected is larger than an angle (θ11 in FIG. 8) between this coupling part 13 or 23 and the second support part 14 or 24 to which this coupling part 13 or 23 is connected. FIG. 8 shows a configuration in the case where θ11 is 120° and θ12 is 150°. In the configuration in FIG. 8, the distance between each of the distal ends of the pairs of arm parts 12 and 22 and the rotation axis R0 is increased compared to Embodiment 1 above, so that a larger change in moment of inertia can be generated when these arm parts 12 and 22 are driven. Accordingly, the driving efficiency can be further increased compared to Embodiment 1 above.

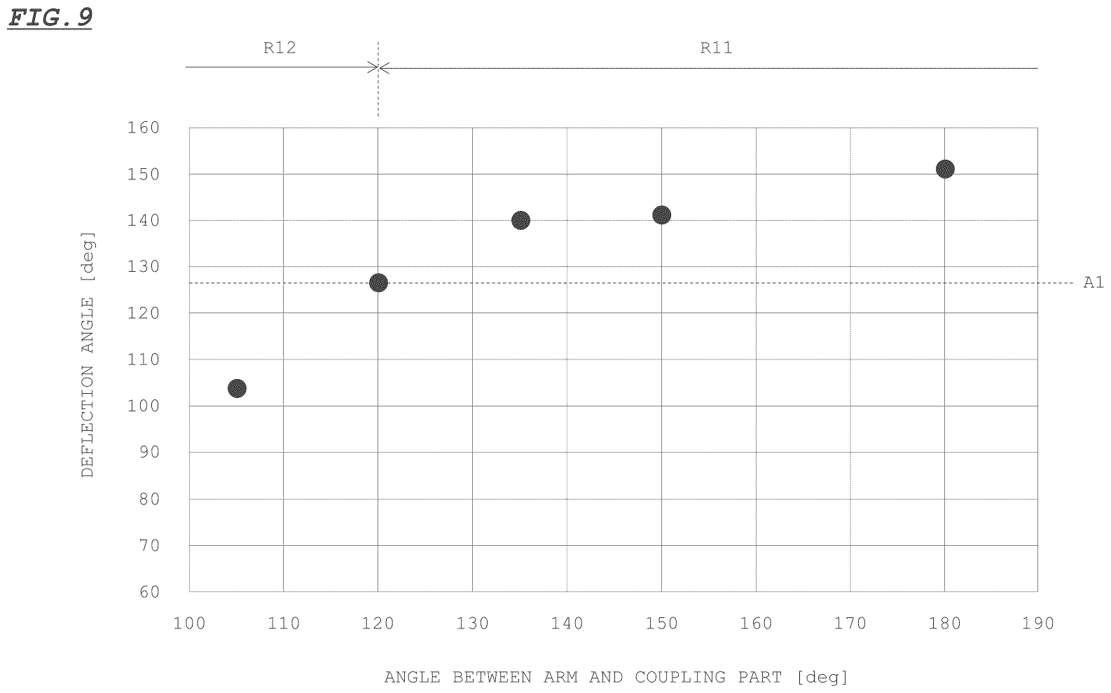

FIG. 9 is a graph showing a simulation result of a deflection angle.

The horizontal axis of the graph in FIG. 9 indicates an angle between the inner side of each arm part 12 or 22 and the coupling part 13 or 23 to which this arm part 12 or 22 is connected (corresponding to the angle θ21 in FIG. 8). In addition, the vertical axis indicates the deflection angle of the movable part 30 (total optical angle), as with the vertical axis on the right side of FIG. 6.

In this simulation, the angle between the inner side of each arm part 12 or 22 and each coupling part 13 or 23 was changed by changing the inclination of the pairs of arm parts 12 and 22 in a state where the angle between each coupling part 13 or 23 and each second support part 14 or 24 was fixed at θ11 shown in FIG. 8, that is, at 120°. Then, for each angle, the deflection angle of the movable part 30 when each tuning fork part U1 was resonated in the mode in FIG. 5 was obtained by simulation. The deflection angle was obtained as a deflection angle (total optical angle) when a voltage of 10 Vpp was applied to the drive parts 16 and 26 (piezoelectric drivers). The other simulation conditions were the same as in the case of FIG. 6.

In FIG. 9, the deflection angle at 120° on the horizontal axis is the same as the deflection angle at 120° on the horizontal axis in FIG. 6. That is, in the case of 120° on the horizontal axis, the pairs of arm parts 12 and 22 are parallel to the rotation axis R0, and the angle between the inner side of each arm part 12 or 22 and each coupling part 13 or 23 is equal to the angle between each coupling part 13 or 23 and each second support part 14 or 24.

A range R11 corresponds to a range where the angle between the inner side of each arm part 12 or 22 and each coupling part 13 or 23 is greater than 120° which is the angle between each coupling part 13 or 23 and each second support part 14 or 24. That is, in this range R11, the pairs of arm parts 12 and 22 are each further away from the rotation axis R0 at the distal end thereof than at the proximal end thereof. In addition, a range R12 corresponds to a range where the angle between the inner side of each arm part 12 or 22 and each coupling part 13 or 23 is smaller than 120° which is the angle between each coupling part 13 or 23 and each second support part 14 or 24. That is, in this range R12, the pairs of arm parts 12 and 22 are each closer to the rotation axis R0 at the distal end thereof than at the proximal end thereof.

From the simulation result in FIG. 9, the deflection angle when the same voltage (10 Vpp) was applied increased as the angle between the inner side of each arm part 12 or 22 and each coupling part 13 or 23 became larger than the angle between each coupling part 13 or 23 and each second support part 14 or 24) (120°), so that the driving efficiency of the movable part 30 was improved. On the other hand, when the angle between the inner side of each arm part 12 or 22 and each coupling part 13 or 23 became smaller than the angle between each coupling part 13 or 23 and each second support part 14 or 24) (120°), the deflection angle became smaller than that when these angles were the same, so that the driving efficiency of the movable part 30 was decreased.

Therefore, from this simulation result, it can be said that, by placing each arm part 12 or 22 such that the arm part 12 or 22 is further away from the rotation axis R0 at the distal end thereof than at the proximal end thereof and making the angle between the inner side of each arm part 12 or 22 and each coupling part 13 or 23 larger than the angle between each coupling part 13 or 23 and each second support part 14 or 24, the driving efficiency of the movable part 30 can be further improved compared to the configuration of Embodiment 1 above.

In the configuration shown in FIG. 8, the distance in the X-axis direction between the distal ends of each pair of arm parts 12 or 22 is larger than that in Embodiment 1 above, so that the outer shape of the drive element 1 in a plan view is larger in the X-axis direction than that in the configuration of Embodiment 1 above. Therefore, it can be said that it is preferable to increase the angle between the inner side of each arm part 12 or 22 and each coupling part 13 or 23 under the condition that the outer shape of the drive element 1 in a plan view can be kept within the range of a predetermined constraint.

### Effects of Embodiment 2

As shown in FIG. 8, the angle θ21 between the rotation axis R0 side of each arm part 12 or 22 and each coupling part 13 or 23 is larger than the angle θ11 between each coupling part 13 or 23 and each second support part 14 or 24. Accordingly, as shown in FIG. 9, the deflection angle of the movable part 30 (total optical angle) at the same voltage (10 Vpp) can be further increased compared to Embodiment 1, so that the driving efficiency of the movable part 30 can be further improved.

The configuration of Embodiment 2 can also be applied to the case where there is no condition that the angle between each coupling part 13 or 23 and each second support part 14 or 24 is greater than 90° and equal to or less than around 135°

### Embodiment 3

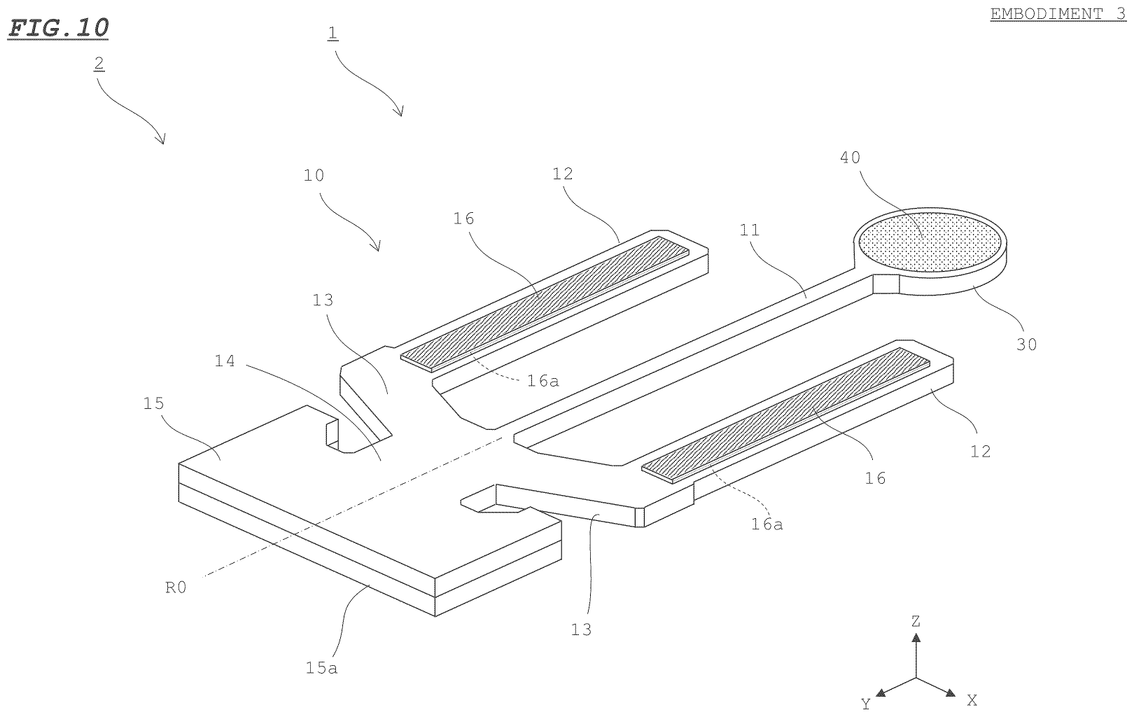

FIG. 10 is a perspective view showing a configuration of a drive element 1 according to Embodiment 3.

In Embodiment 3, the second drive unit 20 shown in Embodiment 1 above is omitted, and the first drive unit 10 is placed only on the Y-axis positive side of the movable part 30. In this configuration as well, as in Embodiment 1 above, the reflection surface 40 is placed on the upper surface of the movable part 30, whereby the light deflection element 2 is configured.

In Embodiment 3 as well, as in Embodiment 1 above, stress concentration occurring at the positions where the pair of coupling parts 13 are joined to the second support part 14 can be reduced, and the driving efficiency of the movable part 30 can be increased.

The configuration of Embodiment 2 may be applied to the configuration of Embodiment 3. In this case, the pair of arm parts 12 are each placed so as to be further away from the rotation axis R0 at the distal end thereof than at the proximal end thereof. Accordingly, as in Embodiment 2, the driving efficiency of the movable part 30 can be further increased.

### Modifications

The embodiments of the present invention are not limited to Embodiments 1 to 3 above.

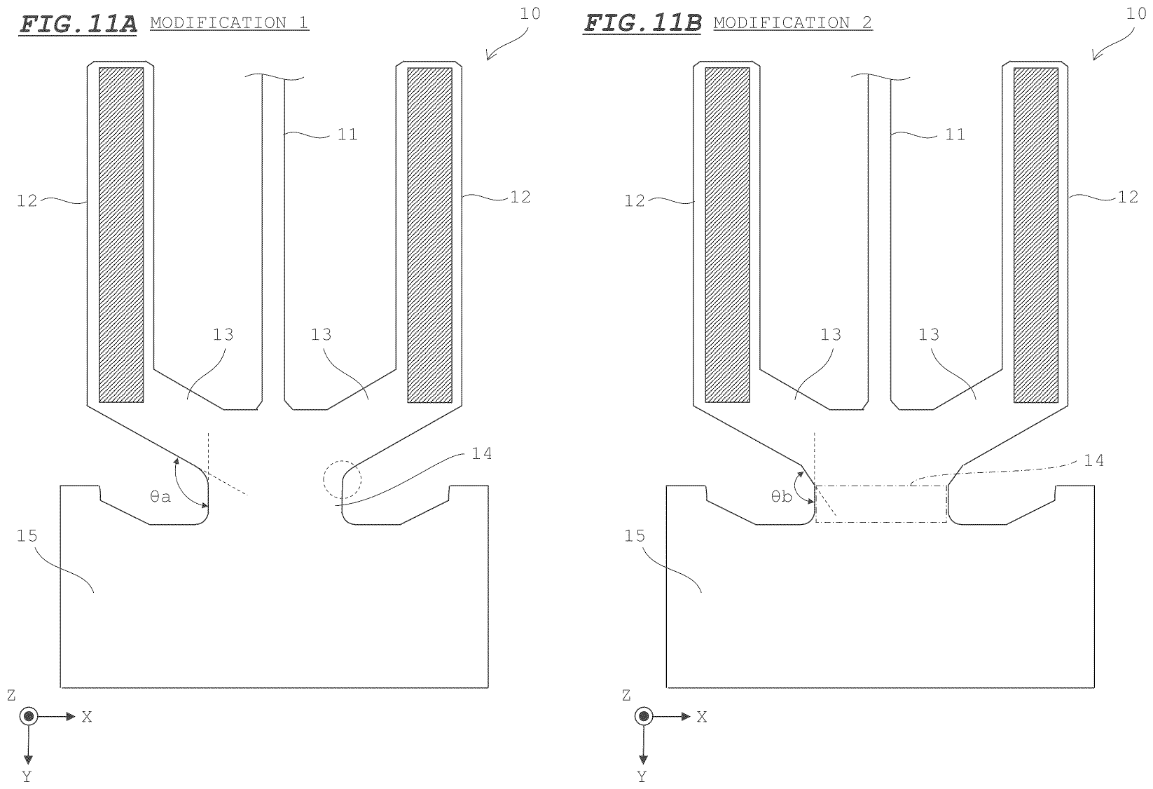

For example, as in Modification 1 shown in FIG. 11A, a corner portion where each side surface on the fixation part 15 side of the pair of coupling parts 13 is joined to the side surface of the second support part 14 (dashed circle portion) is chamfered to form a curved surface. In this case, an angle between each side surface on the fixation part 15 side of the pair of coupling parts 13 and the side surface of the second support part 14 may be greater than 90° and equal to or less than around 135°.

As in Modification 2 shown in FIG. 11B, another side surface may be interposed between the outer surface of each coupling part 13 and the outer surface of the second support part 14. In this case, as shown in FIG. 11B, the range up to the other side surface is the second support part 14, and the other side surface is included in the coupling part 13. Therefore, in this case, an angle θb between the other side surface and the second support part 14 may be set to be greater than 90° and equal to or less than around 135°.

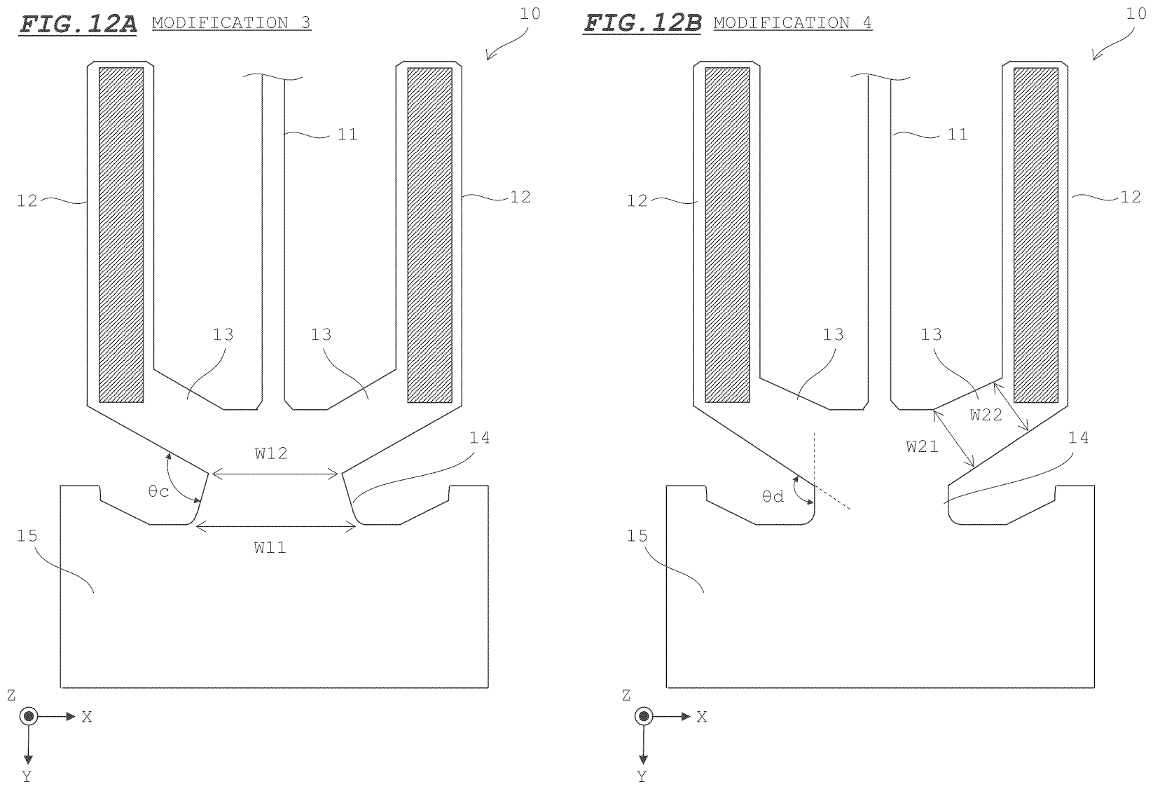

The width of the second support part 14 in the X-axis direction does not have to be constant. For example, as in Modification 3 shown in FIG. 12A, the width of the second support part 14 may vary in the range from W11 to W12. In this case as well, an angle θc between each of the pair of coupling parts 13 and the second support part 14 may be greater than 90° and equal to or less than around 135°.

The width of each coupling part 13 does not have to be constant. For example, as in Modification 4 shown in FIG. 12B, the width of each coupling part 13 may vary in the range from W21 to W22. In this case as well, an angle θd between each of the pair of coupling parts 13 and the second support part 14 may be greater than 90° and equal to or less than around 135°.

FIG. 11A to FIG. 12B each show the configuration on the first drive unit 10 side. However, if the drive element 1 includes the second drive unit 20 as in Embodiments 1 and 2 above, the configuration on the second drive unit 20 side may also be changed in the same manner.

In Embodiments 1 and 2 above, by making the widths in the X-axis direction of the second support parts 14 and 24 wider than the widths in the X-axis direction of the first support parts 11 and 21, the rigidity of the second support parts 14 and 24 is made higher than the rigidity of the first support parts 11 and 21, but the method for increasing the rigidity of the second support parts 14 and 24 is not limited thereto. For example, the rigidity of the second support parts 14 and 24 may be made higher than the rigidity of the first support parts 11 and 21 by a method of making the thicknesses of the second support parts 14 and 24 larger than the thicknesses of the first support parts 11 and 21 or a method of forming the second support parts 14 and 24 from a material having higher rigidity than the first support parts 11 and 21.

In Embodiments 1 and 2 above, the shape of the movable part 30 is circular, but the shape of the movable part 30 may be another shape such as a square shape. The shape of the drive element 1 in a plan view and the dimensions of each part of the drive element 1 can also be changed as appropriate.

The drive element 1 may be used as an element other than the light deflection element 2. In the case where the drive element 1 is used as an element other than the light deflection element, the reflection surface 40 does not have be located on the movable part 30, and a member other than the reflection surface 40 may be placed on the movable part 30.

In addition to the above, various modifications can be made as appropriate to the embodiments of the present invention without departing from the scope of the technical idea defined by the claims.

### Additional Notes

The following technologies are disclosed by the description of the above embodiments.

### (Technology 1)

A drive element including:
a movable part;
a first support part extending along a rotation axis of the movable part and connected at one end thereof to the movable part;
a pair of arm parts placed with the rotation axis located therebetween;
a pair of coupling parts coupling the pair of arm parts to another end of the first support part;
a second support part extending along the rotation axis and supporting the pair of coupling parts;
a fixation part to which the second support part is connected; and
drive parts configured to drive the arm parts, respectively, wherein
the second support part has higher rigidity than the first support part,
the pair of coupling parts are placed so as to be inclined toward the movable part side, and
an angle between each of the coupling parts and the second support part is greater than 90° and equal to or less than 135°.

According to this technology, since the pair of coupling parts are placed so as to be inclined toward the movable part side, and the angle between each of the coupling parts and the second support part is greater than 90° and equal to or less than 135°, even when the rigidity of the second support part is higher than that of the first support part, stress generated at the connection position between each coupling part and the second support part when the movable part is driven can be reduced, so that torques generated at the pair of arm parts can be efficiently transmitted to the first support part. Therefore, it is possible to effectively increase the driving efficiency of the movable part while reducing the stress generated when the movable part is driven.

### (Technology 2)

The drive element according to Technology 1, wherein the angle is set to around 115°.

According to this technology, the driving efficiency of the movable part can be increased the most.

### (Technology 3)

The drive element according to Technology 1 or 2, wherein an angle between the rotation axis side of each of the arm parts and each of the coupling parts is larger than the angle between each of the coupling parts and the second support part.

According to this technology, the driving efficiency of the movable part can be further increased.

### (Technology 4)

The drive element according to Technology 1 or 2, wherein the pair of arm parts extend parallel to the rotation axis.

According to this technology, it is possible to reduce the stress and improve the driving efficiency of the movable part while keeping the outer shape of the drive element in a plan view compact.

### (Technology 5)

The drive element according to any one of Technologies 1 to 4, wherein
two drive units each including the first support part, the pair of arm parts, the pair of coupling parts, the second support part, the fixation part, and the drive parts are placed in orientations opposite to each other with the movable part located therebetween, and
the first support part of each drive unit is connected to the movable part.

According to this technology, by supporting and driving the movable part by each drive unit, the movable part can be stably driven with a larger torque.

### (Technology 6)

The drive element according to any one of Technologies 1 to 5, wherein the drive parts each have a piezoelectric thin film as a drive source.

According to this technology, the arm parts can be smoothly driven.

### (Technology 7)

A light deflection element including:
the drive element according to any one of Technologies 1 to 6; and
a reflection surface located on the movable part.

According to this technology, the driving efficiency of the movable part can be increased by the drive element according to any one of Technologies 1 to 6, so that the reflection surface allows deflection of and scanning with light to be efficiently performed at a high deflection angle.

Furthermore, the following technologies are disclosed by the description of Embodiment 2.

### (Technology 8)

A drive element including:
a movable part;
a first support part extending along a rotation axis of the movable part and connected at one end thereof to the movable part;
a pair of arm parts placed with the rotation axis located therebetween;
a pair of coupling parts coupling the pair of arm parts to another end of the first support part;
a second support part extending along the rotation axis and supporting the pair of coupling parts;
a fixation part to which the second support part is connected; and
drive parts configured to drive the arm parts, respectively, wherein
the pair of arm parts are each placed so as to be further away from the rotation axis at a distal end thereof than at a proximal end thereof.

### (Technology 9)

The drive element according to Technology 8, wherein an angle between the rotation axis side of each of the arm parts and each of the coupling parts is larger than an angle between each of the coupling parts and the second support part.

According to Technologies 8 and 9, the driving efficiency of the movable part can be increased.

What is claimed is:

1. A drive element comprising:
a movable part;
a first support part extending along a rotation axis of the movable part and connected at one end thereof to the movable part;
a pair of arm parts placed with the rotation axis located therebetween;
a pair of coupling parts coupling the pair of arm parts to another end of the first support part;
a second support part extending along the rotation axis and supporting the pair of coupling parts;
a fixation part to which the second support part is connected; and
drive parts configured to drive the arm parts, respectively, wherein
the second support part has higher rigidity than the first support part,
the pair of coupling parts are placed so as to be inclined toward the movable part side, and
an angle between each of the coupling parts and the second support part is greater than 90° and equal to or less than 135°.

2. The drive element according to claim 1, wherein the angle is set to around 115°.

3. The drive element according to claim 1, wherein an angle between the rotation axis side of each of the arm parts and each of the coupling parts is larger than the angle between each of the coupling parts and the second support part.

4. The drive element according to claim 1, wherein the pair of arm parts extend parallel to the rotation axis.

5. The drive element according to claim 1, wherein
two drive units each including the first support part, the pair of arm parts, the pair of coupling parts, the second support part, the fixation part, and the drive parts are placed in orientations opposite to each other with the movable part located therebetween, and
the first support part of each drive unit is connected to the movable part.

6. The drive element according to claim 1, wherein the drive parts each have a piezoelectric thin film as a drive source.

7. A light deflection element comprising:
the drive element according to claim 1; and
a reflection surface located on the movable part.
